(19) United States
(12) Patent Application Publication
(10) Pub. No.: US 2026/0112433 A1
(43) Pub. Date: Apr. 23, 2026

(54) VOLTAGE PROVISION CIRCUITS WITH VOLTAGE DETECTOR AND METHODS FOR OPERATING THE SAME

(71) Applicant: Taiwan Semiconductor Manufacturing Company, Ltd., Hsinchu (TW)

(72) Inventors: I-Hsin Yang, Hsinchu City (TW); Meng-Sheng Chang, Hsinchu City (TW)

(73) Assignee: Taiwan Semiconductor Manufacturing Company, Ltd., Hsinchu (TW)

(21) Appl. No.: 18/921,340

(22) Filed: Oct. 21, 2024

(51) Int. Cl. G11C 17/18; G11C 17/16; H03K 19/20

(52) U.S. Cl. CPC G11C 17/18; G11C 17/16; H03K 19/20

(57) ABSTRACT

A circuit includes a memory array comprising a plurality of memory cells; and a voltage provision circuit configured to provide an operation voltage for one or more of the plurality of memory cells, the operation voltage being shifted from a first voltage domain to a second voltage domain. The voltage provision circuit comprises a voltage detector. The voltage detector is configured to receive a first supply voltage in the first voltage domain, powered by a second supply voltage in the second voltage domain, and provide a first control signal. The first control signal is configured to determine whether the operation voltage is equal to the second supply voltage at a first logic state or the second supply voltage at a second logic state.

### BACKGROUND

The semiconductor industry has experienced rapid growth due to continuous improvements in the integration density of a variety of electronic components (e.g., transistors, diodes, resistors, capacitors, etc.). For the most part, this improvement in integration density has come from repeated reductions in minimum feature size, which allows more components to be integrated into a given area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example block diagram of a memory circuit, in accordance with some embodiments.

FIG. 2 illustrates an example schematic diagram of a memory cell of the memory circuit of FIG. 1, in accordance with some embodiments.

FIG. 3 illustrates an example circuit diagram of a voltage provision circuit coupled to or integrated with the memory circuit of FIG. 1, in accordance with some embodiments.

FIG. 4 illustrates an example circuit diagram of a voltage detector included in the voltage provision circuit of FIG. 3, in accordance with some embodiments.

FIG. 5 illustrates an example circuit diagram of a voltage provision circuit coupled to or integrated with the memory circuit of FIG. 1, in accordance with some embodiments.

FIG. 6 illustrates an example circuit diagram of a voltage provision circuit coupled to or integrated with the memory circuit of FIG. 1, in accordance with some embodiments.

FIG. 7 illustrates an example circuit diagram of a voltage provision circuit coupled to or integrated with the memory circuit of FIG. 1, in accordance with some embodiments.

FIG. 8 illustrates an example circuit diagram of a voltage provision circuit coupled to or integrated with the memory circuit of FIG. 1, in accordance with some embodiments.

FIG. 9 illustrates an example circuit diagram of a voltage provision circuit coupled to or integrated with the memory circuit of FIG. 1, in accordance with some embodiments.

FIG. 10 illustrates an example circuit diagram of a voltage provision circuit coupled to or integrated with the memory circuit of FIG. 1, in accordance with some embodiments.

FIG. 11 illustrates an example circuit diagram of a voltage provision circuit coupled to or integrated with the memory circuit of FIG. 1, in accordance with some embodiments.

FIG. 12 illustrates an example flow chart of a method for providing an operation voltage to a memory circuit, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

With the ever increasing pace to advance to the next generation nodes, input/output (I/O) needs of a system typically deal with transferring signals between integrated circuit dies and component connections having large capacitances, such as those associated with printed circuit board traces, cables etc., that require larger driving power and voltage than the signaling occurring within the integrated circuit die. I/O devices interface the faster, smaller signals of a main die to these other, higher capacitance components, and typically transfer the signals at higher voltages. As a non-limiting example, a memory circuit (e.g., an efuse memory circuit or otherwise one-time programmable (OTP) memory circuit) typically relies on an I/O circuit to provide a high voltage for operation of the memory circuit (e.g., programing, erasing, etc.).

A voltage provision circuit is one of various such I/O circuits, operatively coupled to a memory circuit, that can provide a desired operation voltage (e.g., a relatively high operation voltage). Such a voltage provision circuit typically includes a level shifter, which, in general, can shift the level of a supply voltage from one voltage domain to another voltage domain. For example, when a memory cell of the memory circuit is configured in a program mode, the voltage provision circuit generally provides the memory cell with an operation voltage shifted from a first (e.g., lower) voltage domain to a second (e.g., higher) voltage domain. The voltage provision circuit may receive a first supply voltage and a second supply voltage, both with a logic high state but respectively in the first and second voltage domains, and provide the memory cell with the operation (e.g., program) voltage equal to the second supply voltage in the logic high state.

However, in certain scenarios, the first supply voltage may be erroneously provided in a logic low state, with the second supply voltage being provided in the logic high state. As such, the existing voltage provision circuit may provide the operation voltage equal to the same second supply voltage in the logic high state, which causes the memory circuit to malfunction. For example, if the first supply voltage is in the logic low state, various circuit components (e.g., control circuits) powered by the first supply voltage may not properly function. By providing the memory cell with the high operation voltage while these control circuits are improperly functioning, the memory cell may be mis-programmed. Thus, the existing voltage provision circuit of a memory circuit has not been entirely satisfactory in certain aspects.

The present disclosure provides various embodiments of a voltage provision circuit operatively coupled to a memory array, e.g., providing an operation voltage to the memory array based on a configurated operation mode of the memory array. In some embodiments, the voltage provision circuit can include a voltage detector configured to receive a first supply voltage and powered by a second supply voltage. Upon detecting that the first supply voltage is provided with a logic low state while the second supply voltage is provided at a logic high state, the voltage detector can provide a control signal to a logic gate (e.g., a NOR gate) of the voltage provision circuit to forcibly cause an output stage of the voltage provision circuit to provide the operation voltage equal to the second supply voltage at the logic low state (e.g., a ground voltage). As a result, even though the first/second supply voltages are provided with erroneous logic states, the voltage provision circuit, as disclosed herein, can forcibly pull down the operation voltage to the ground voltage, thereby avoiding the coupled memory array from further malfunctioning.

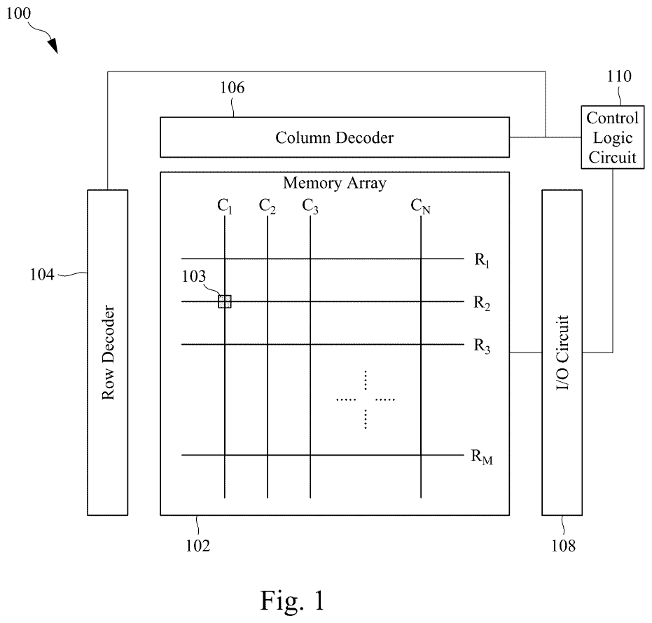

FIG. 1 illustrates a memory circuit 100, in accordance with various embodiments. In the illustrated embodiment of FIG. 1, the memory circuit 100 includes a memory array 102, a row decoder 104, a column decoder 106, an input/output (I/O) circuit 108, and a control logic circuit 110. Despite not being shown in FIG. 1, the components of the memory circuit 100 may be operatively coupled to each other and to the control logic circuit 110. Although, in the illustrated embodiment of FIG. 1, each component is shown as a separate block for the purpose of clear illustration, in some other embodiments, some or all of the components shown in FIG. 1 may be integrated together. For example, the I/O circuit 108 may be embedded (or integrated) in the memory array 102.

The memory array 102 is a hardware component that stores data. In one aspect, the memory array 102 is embodied as a semiconductor memory device. The memory array 102 includes a plurality of memory cells (or otherwise storage units) 103. The memory array 102 includes a number of rows R₁, R₂, R₃ . . . . R_{M}, each extending in a first direction (e.g., the X-direction) and a number of columns C₁, C₂, C₃ . . . . C_{N}, each extending in a second direction (e.g., the Y-direction). Each of the rows/columns may include one or more conductive structures. In some embodiments, each memory cell 103 is arranged in the intersection of a corresponding row and a corresponding column and can be operated according to voltages or currents through the respective conductive structures of the column and row.

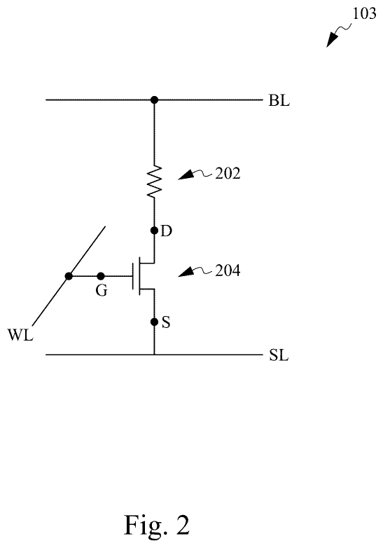

In accordance with various embodiments of the present disclosure, each memory cell 103 may be implemented as a one-time-programmable (OTP) memory cell. For example, the memory cell 103 may be an efuse cell, which includes at least a fuse resistor and an access transistor coupled in series. However, it should be understood that the memory cell 103 can be implemented as any of various other memory configurations, e.g., a static random access memory (SRAM) cell, a phase-change random access memory (PCRAM) cell, a resistive random access memory (RRAM) cell, a magnetoresistive (MRAM) random access memory cell, or the like, while remaining with the scope of the present disclosure. Detailed descriptions of the memory cell 103, configured as an efuse cell, will be discussed below with respect to FIG. 2.

The row decoder 104 is a hardware component that can receive a row address of the memory array 102 and assert a conductive structure (e.g., a word line) at that row address. The column decoder 106 is a hardware component that can receive a column address of the memory array 102 and assert one or more conductive structures (e.g., a bit line, a source line) at that column address. The I/O circuit 108 is a hardware component that can access (e.g., read, program) each of the memory cells 103 asserted through the row decoder 104 and column decoder 106. The control logic circuit 110 is a hardware component that can control the coupled components (e.g., 102 through 108).

FIG. 2 illustrates an example configuration of the memory cell 103 (FIG. 1) configured as an efuse cell (hereinafter “efuse cell 103”), in accordance with some embodiments. The efuse cell 103 is implemented as a 1T1R configuration, for example, a fuse resistor 202 serially connected to an access transistor 204. It, however, should be understood that any of various other fuse configurations that exhibit the fuse characteristic may be used by the efuse cell 103 such as, for example, a 2-diodes-1-resistor (2D1R) configuration, a many-transistors-one-resistor (manyT1R) configuration, etc., while remaining within the scope of the present disclosure.

The fuse resistor 202 is formed of one or more metal structures. For example, the fuse resistor 202 may be one of a number of interconnect structures in one of a number of metallization layers that are disposed above the access transistor 204. The access transistor 204 can be formed over the major surface of a semiconductor substrate, which is sometimes referred to as part of front-end-of-line (FEOL) processing. Over the FEOL processing, a number of metallization layers, each of which includes a number of interconnect (e.g., metal) structures, are typically formed, which are sometimes referred to as part of back-end-of-line (BEOL) processing.

With the fuse resistor 202 (of the efuse cell 103) embodied as a metal structure, the fuse resistor 202 may present an initial resistance value (or resistivity), for example, as fabricated. To program the efuse cell 103, the access transistor 204 (if embodied as an n-type transistor) is turned on by applying a (e.g., voltage) signal, corresponding to a logic high state, through a word line (WL) to a gate terminal of the access transistor 204. Concurrently or subsequently, a sufficiently high voltage (e.g., a program voltage) is applied on one of the terminals of the fuse resistor 202 through a bit line (BL). With the access transistor 204 turned on to provide a (e.g., program) path from the BL, through the resistor 202 and transistor 204, and to a source line (SL), such a high voltage signal can burn out a portion of the corresponding metal structure (the fuse resistor 202), thereby transitioning the fuse resistor 202 from a first state (e.g., a short circuit) to a second state (e.g., an open circuit). Accordingly, the efuse cell 103 can irreversibly transition from a first logic state (e.g., logic 0) to a second logic state (e.g., logic 1), which can be read out by applying a relatively low voltage signal on the BL and turning on the access transistor 204 to provide a (e.g., read) path. In various embodiments of the present disclosure, such a high program voltage, shifted up from a first voltage domain to a second voltage domain, can be provided by a voltage provision circuit of the I/O circuit 108, which will be discussed in further detail below.

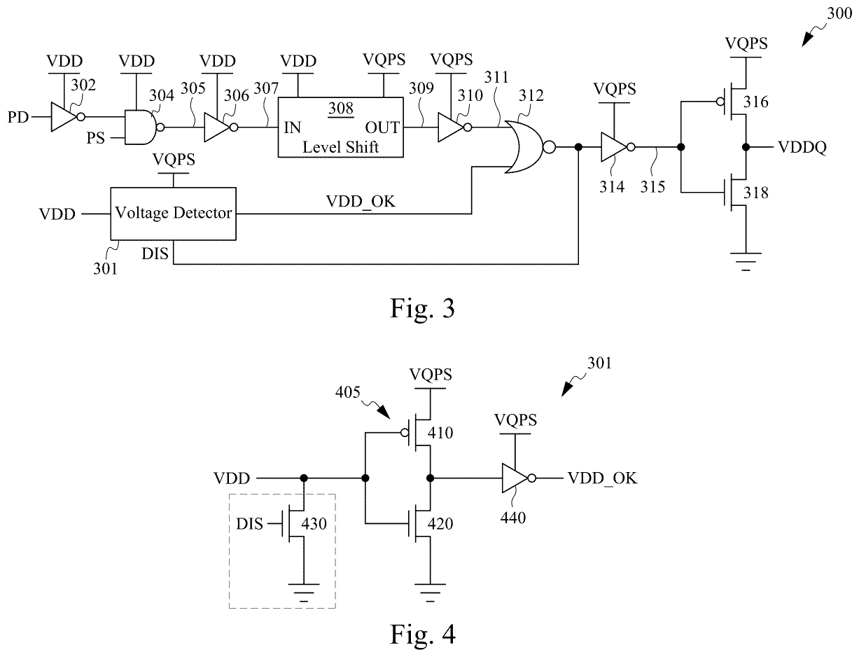

FIG. 3 illustrates an example circuit diagram of a voltage provision circuit 300 of the I/O circuit 108, in accordance with some embodiments. The voltage provision circuit 300 can provide an operation voltage (VDDQ) configured for programming the efuse cell 103. The voltage provision circuit 300 can provide the operation voltage VDDQ shifted from a first voltage domain to a second voltage domain. The first voltage domain may be in a range between a ground voltage and a first supply voltage (VDD); and the second voltage domain may be in a range between the ground voltage and a second supply voltage (VQPS). The first supply voltage is equal to 0V when provided at a logic low state, and equal to around 0.75V when provided at a logic high state; and the second supply voltage is equal to 0V when provided at the logic low state, and equal to around 1.8V when provided at the logic high state.

In some embodiments, the voltage provision circuit 300 can include a voltage detector (e.g., 301 of FIG. 4) configured to detect whether the first supply voltage VDD has been properly provided, and if the voltage detector identifies that first supply voltage VDD is provided with the logic low state and the second supply voltage VQPS is provided with the logic high state (e.g., 0V and 1.8V, respectively), the voltage detector 301 can provide a control signal to a logic gate of the voltage provision circuit 300 to forcibly pull the operation voltage VDDQ to 0V. Details of the voltage detector 301 will be discussed below.

Referring first to FIG. 3, the voltage provision circuit 300 includes inverter 302, NAND gate 304, inverter 306, level shifter 308, inverter 310, NOR gate 312, inverter 314, pull-up transistor 316, pull-down transistor 318, and voltage detector 301. In some embodiments, the inverter 302, NAND gate 304, and inverter 306 can operate in the first voltage domain (e.g., between 0V and 0.75V); and the inverter 310, NOR gate 312, inverter 314, pull-up transistor 316, pull-down transistor 318, and voltage detector 301 can operate in the second voltage domain (e.g., between 0V and 1.8V).

The inverter 302 can receive a control signal PD (e.g., through a first control pin), and provide the inverted control signal PD to one of the inputs of the inverter 304. The NAND gate 304 can receive another control signal PS (e.g., through a second control pin), and perform a NAND operation on the control signal PD inverted and the control signal PS to provide signal 305. In some embodiments, the control signal PD and control signal PS are both provided with the logic low state (i.e., PD=0 and PS=0), when the coupled efuse cell 103 is configured in a read mode; and the control signal PD and control signal PS are respectively provided with the logic low state and the logic high state (i.e., PD=0 and PS=1), when the coupled efuse cell 103 is configured in a program mode. The control signals PD and PS, with respective logic states, can be provided in the first voltage domain. For example, when configured at the logic high state, the control signal PD/PS is provided at 0.75V; and when configured at the logic low state, the control signal PD/PS is provided at 0V.

The inverter 306 can provide signal 307 to the level shifter 308 by inverting the NAND′ed signal 305. The level shifter 308 can shift the signal 307 (e.g., a voltage of which is equal to 0V when at the logic low state or 0.75V when at the logic high state) so as to provide signal 309 (e.g., a voltage of which is equal to 0V when at the logic low state or 1.8V when at the logic high state). For example, when the signal 307 is received by the level shifter 308 with the logic high state, the level shifter 308 can provide the signal 309 with the logic high state, where the signal 307 and signal 309 are around 0.75V and 1.8V, respectively. The inverter 310 can provide signal 311 to one of the inputs of the NOR gate 312 by inverting the signal 309. The NOR gate 312 can receive another input signal (e.g., control signal VDD_OK) and perform a NOR operation on the signal 311 and the control signal VDD_OK to provide control signal DIS. The inverter 314 can provide signal 315 by inverting the control signal DIS. The pull-up transistor 316 can have its gate terminal receiving the signal 315, and the pull-down transistor 318 can have its gate terminal receiving the signal 315. Further, the pull-up transistor 316 (which may be implemented as a p-type transistor) can have its source terminal connected to the second supply voltage VQPS, and the pull-down transistor 318 (which may be implemented as an n-type transistor) can have its source terminal connected to the ground voltage, where respective drain terminals of the transistors 316 and 318 are connected to each other at an output node to provide the operation voltage VDDQ.

Referring next to FIG. 4, an example circuit diagram of the voltage detector 301 is shown, in accordance with some embodiments. The voltage detector 301 includes inverter 405 formed by pull-up transistor 410 and pull-down transistor 420, transistor 430, and Schmitt trigger 440. The pull-up transistor 410 and the pull-down transistor 420 may be implemented as a p-type transistor and an n-type transistor, respectively. The pull-up transistor 410 can have its source terminal connected to the second supply voltage VQPS, and the pull-down transistor 420 can have its source terminal connected to the ground voltage. Respective gate terminals of the transistors 410 and 420 are connected to each other, operatively serving as an input terminal of the inverter 405, and respective drain terminals of the transistors 410 and 420 are connected to each other, operatively serving an output terminal of the inverter 405. The input terminal of the inverter 405 is configured to receive the first supply voltage VDD, and coupled to the ground voltage through the transistor 430 gated by the control signal DIS. The output terminal of the inverter 405 is connected to an input terminal of the Schmitt trigger 440, which operatively serves as a power noise filter. The Schmitt trigger 440 can provide the control signal VDD_OK by filtering the logically inverted first supply voltage VDD. For example, when the first supply voltage VDD and the second supply voltage VQPS are provided with the logic low state and logic high state, respectively, the control signal VDD_OK can be provided with the logic high state.

In operation, the voltage provision circuit 300 can provide the operation voltage VDDQ equal to the VQPS at the logic high state (e.g., about 1.8V), when the coupled memory cell 103 is configured to be programmed; and provide the operation voltage VDDQ equal to the VQPS at the logic low state (e.g., about 0V), when the coupled memory cell 103 is configured to be read. Further, when in the read mode, the first supply voltage VDD and second supply voltage VQPS are both provided with the logic high state (i.e., VDD=1 and VQPS=1), and the control signal PD and control signal PS are both provided with the logic low state (i.e., PD=0 and PS=0). As such, the signal 307, input to the level shifter 308, is at the logic low state, and the signal 309, output from the level shifter 308, is also at the logic low state. The NOR gate 312 can then output the control signal DIS at the logic low state, which causes the transistors 316 and 318, operatively serving as an inverter, to output the operation voltage VDDQ equal to about 0V. When in the program mode, the control signal PD and control signal PS are respectively provided with the logic low state and the logic high state (i.e., PD=0 and PS=1). As such, the signal 307, input to the level shifter 308, is at the logic high state, and the signal 309, output from the level shifter 308, is also at the logic high state. The NOR gate 312 can then output the control signal DIS at the logic high state, which causes the transistors 316 and 318, operatively serving as an inverter, to output the operation voltage VDDQ equal to about 1.8V.

In some scenarios, the first supply voltage VDD and second supply voltage VQPS may be (e.g., erroneously) provided with the logic low state and the logic high state, respectively (i.e., VDD=0 and VQPS=1), while the control signals PD and PS can be in any arbitrary logic combination. With VDD=0, the inverter 405 of the voltage detector 301 can output the control signal VDD_OK at the logic high state by inverting the VDD. Accordingly, the NOR gate 312 can then output the control signal DIS at the logic low state, regardless of the logic combination of the control signals PD and PS. As a result, the transistors 316 and 318, operatively serving as an inverter, can output the operation voltage VDDQ equal to about 0V.

Table below summarizes various combinations of logic states of the first supply voltage VDD, the second supply voltage VQPS, the operation voltage VDDQ, the control signal VDD_OK, and the control signal DIS. For example, when the operation voltage VDDQ is at the logic low state, the operation voltage VDDQ is equal to the second supply voltage VQPS at the logic high state (e.g., about 1.8V); and when the operation voltage VDDQ is at the logic low state, the operation voltage VDDQ is equal to the second supply voltage VQPS at the logic low state (e.g., about 0V).

TABLE

| VDD | VQPS | VDDQ | VDD_OK | DIS |
|---|---|---|---|---|
| 0 | 0 | 0 | 0 | 0 |
| 0 | 1 | 0 | 1 | 0 |
| 1 | 0 | 0 | 0 | 0 |
| 1 | 1 | 1 | 0 | 1 |

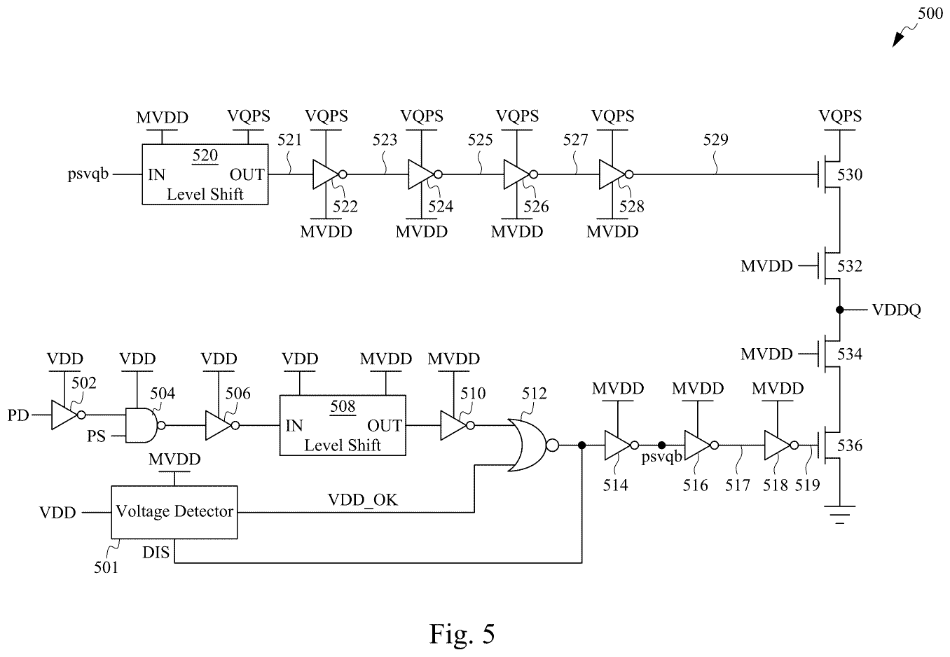

FIG. 5 illustrates an example circuit diagram of a voltage provision circuit 500 of the I/O circuit 108, in accordance with some embodiments. The voltage provision circuit 500 can provide an operation voltage (VDDQ) configured for programming the efuse cell 103. Similar to the voltage provision circuit 300 (FIG. 3), the voltage provision circuit 500 can provide the operation voltage VDDQ shifted from a first voltage domain (e.g., from 0V to about 0.75V) to a second voltage domain (e.g., from 0V to about 1.8V), except that the voltage provision circuit 500 may have its components (e.g., transistors) configured in a stacked structure to lower a voltage drop across any terminals of each of the transistors. Accordingly, the following discussion on the voltage provision circuit 500 will be focused on the difference.

In comparison with the voltage provision circuit 300 (FIG. 3), the voltage provision circuit 500 also includes components 501, 502, 504, 506, 508, 510, and 512, which are similar to the components 310, 302, 304, 306, 308, 310, and 312, respectively, except the following difference. For example, the component 508 (e.g., a level shifter) is configured to shift the first voltage domain, in the range of 0V to VDD (e.g., around 0.75V), to another (third) voltage domain, in the range of 0V to a mid-range supply voltage, MVDD (e.g., around 0.9V). In such embodiments, the mid-range voltage MVDD may be configured as ½×VQPS. In another example, the component 510 (e.g., an inverter), the component 512 (e.g., a NOR gate), and the component 501 (e.g., a voltage detector) operate under the mid-range supply voltage MVDD. Stated another way, the inverter 510, NOR gate 512, and the voltage detector 501 may operate in the third voltage domain, from 0V to about 0.9V.

For example, the voltage detector 501, which can include the components shown in FIG. 4, can have its inverter coupled between the MVDD and the ground voltage. As a result, the voltage detector 501 can receive the first supply voltage VDD in the first voltage domain (from 0V to about 0.75V) and output the control signal VDD_OK in the third voltage domain (from 0V to about 0.9V). For example, the voltage detector 501 can output the control signal VDD_OK at the logic high state (e.g., about 0.9V) upon detecting that the first supply voltage VDD is at the logic low state and the mid-range supply voltage MVDD is at the logic high state.

The voltage provision circuit 500 can further include inverter 514, inverter 516, inverter 518, level shifter 520, inverter 522, inverter 524, inverter 526, inverter 528, first pull-up transistor 530, second pull-up transistor 532, first pull-down transistor 534, and second pull-down transistor 536. In some embodiments, the inverters 514 to 518 may operate in the third voltage domain. The inverter 514 can provide a control signal psvqb by inverting the control signal DIS provided by the NOR gate 512. The inverter 516 can provide signal 517 by inverting the control signal psvqb. The inverter 518 can provide signal 519 by inverting the signal 517. As discussed above with respect to the voltage detector 301 (FIGS. 3-4), the NOR gate 512 can receive the control signal VDD_OK at the logic high state, upon the VDD detector 501 detecting that the first supply voltage VDD is provided with the logic low state but the mid-range supply voltage MVDD is provided with the logic high state.

The level shifter 520 can shift the third voltage domain, in the range of 0V to MVDD (around 0.9V), to yet another (fourth) voltage domain, in the range of MVDD (around 0.9V) to VQPS (around 1.8V). For example, the level shifter 520 can shift the control signal psvqb (e.g., between 0V and about 0.9V) and provide signal 521 (e.g., between about 0.9V and about 1.8V). The inverter 522 can provide signal 523 by inverting the signal 521. The inverter 524 can provide signal 525 by inverting the signal 523. The inverter 526 can provide signal 527 by inverting the signal 525. The inverter 528 can provide signal 529 by inverting the signal 527 As such, when the control signal psvqb is provided with the logic high state (e.g., around 0.9V), the signal 529 can be provided with the logic high state (e.g., around 1.8V).

The pull-up transistor 530 can have its gate terminal receiving the signal 529, the pull-up transistor 532 can have its gate terminal receiving the mid-range supply voltage MVDD, the pull-down transistor 534 can have its gate terminal receiving the mid-range supply voltage MVDD, and the pull-down transistor 536 can have its gate terminal receiving the signal 519. Further, the pull-up transistor 530 (which may be implemented as a p-type transistor) can have its source terminal connected to the second supply voltage VQPS, and its drain terminal connected to a source terminal of the pull-up transistor 532 (which may be implemented as a p-type transistor). The pull-down transistor 536 (which may be implemented as an n-type transistor) can have its source terminal connected to the ground voltage, and its drain terminal connected to a source terminal of the pull-down transistor 534 (which may be implemented as an n-type transistor). Respective drain terminals of the transistors 522 and 534 are connected to each other at an output node to provide the operation voltage VDDQ.

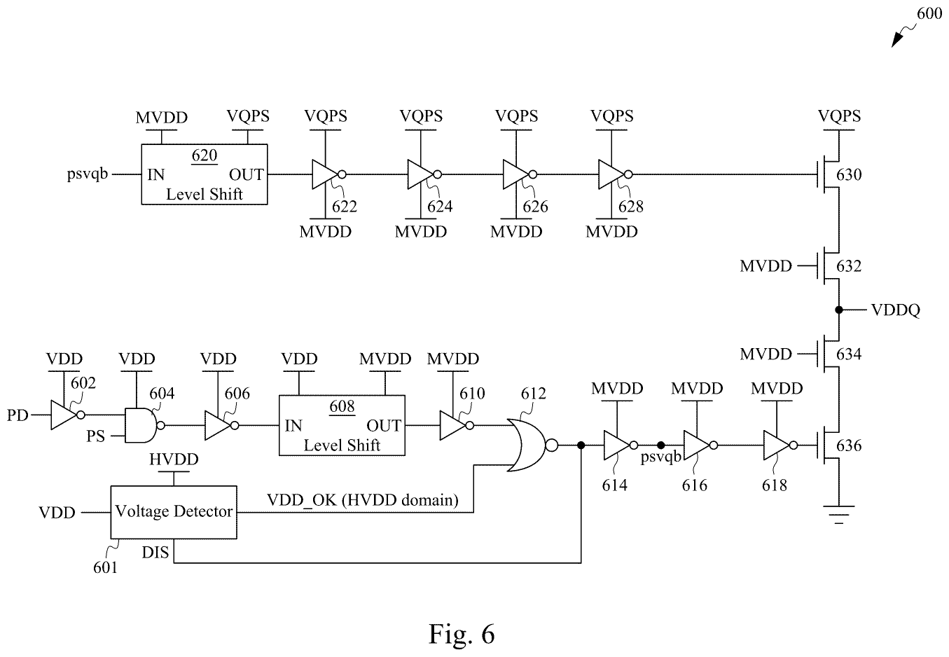

FIG. 6 illustrates an example circuit diagram of a voltage provision circuit 600 of the I/O circuit 108, in accordance with some embodiments. The voltage provision circuit 600 can provide an operation voltage (VDDQ) configured for programming the efuse cell 103. The voltage provision circuit 600 is substantially similar to the voltage provision circuit 500 (FIG. 5), both of which can provide the operation voltage VDDQ shifted from a first voltage domain (e.g., from 0V to about 0.75V) to a second voltage domain (e.g., from 0V to about 1.8V) with a stacked structures, except that the voltage provision circuit 600 may have its voltage detector (e.g., 601) powered by another mid-range supply voltage, HVDD. In such embodiments, and the mid-range supply voltage HVDD may be configured as ⅔×VQPS, with the mid-range voltage MVDD still configured as ½×VQPS. For brevity, the following discussion on the voltage provision circuit 600 will be focused on the difference.

In comparison with the voltage provision circuit 500 (FIG. 5), the voltage provision circuit 600 also includes components 601, 602, 604, 606, 608, 610, 612, 614, 616, 618, 620, 622, 624, 626, 628, 630, 632, 634, and 636, which are similar to the components 501, 502, 504, 506, 508, 510, 512, 514, 516, 518, 520, 522, 524, 526, 528, 530, 532, 534, and 536, respectively, except that the voltage detector 601, which can include the components shown in FIG. 4, can have its inverter coupled between the mid-range supply voltage HVDD (e.g., about 1.2V) and the ground voltage. As a result, the voltage detector 601 can receive the first supply voltage VDD in the first voltage domain (from 0V to about 0.75V) and output the control signal VDD_OK in yet another voltage domain (from 0V to about 1.2V). For example, the voltage detector 601 can output the control signal VDD_OK at the logic high state (e.g., about 1.2V) upon detecting that the first supply voltage VDD is at the logic low state and the mid-range supply voltage HVDD is at the logic high state.

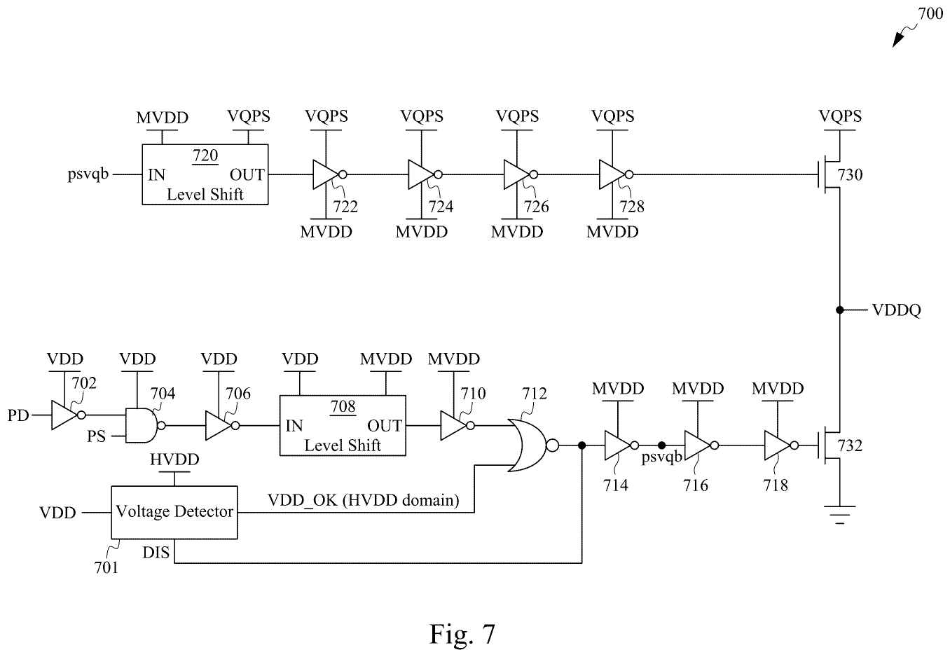

FIG. 7 illustrates an example circuit diagram of a voltage provision circuit 700 of the I/O circuit 108, in accordance with some embodiments. The voltage provision circuit 700 can provide an operation voltage (VDDQ) configured for programming the efuse cell 103. The voltage provision circuit 700 is substantially similar to the voltage provision circuit 600 (FIG. 6), both of which can provide the operation voltage VDDQ shifted from a first voltage domain (e.g., from 0V to about 0.75V) to a second voltage domain (e.g., from 0V to about 1.8V) with a stacked structures, except that the voltage provision circuit 700 may have less pull-up and less pull-down transistors at its output stage. Accordingly, the following discussion on the voltage provision circuit 700 will be focused on the difference.

In comparison with the voltage provision circuit 600 (FIG. 6), the voltage provision circuit 700 also includes components 701, 702, 704, 706, 708, 710, 712, 714, 716, 718, 720, 722, 724, 726, 728, 730, and 732, which are similar to the components 601, 602, 604, 606, 608, 610, 612, 614, 616, 618, 620, 622, 624, 626, 628, 630, 6 and 636, respectively. It should be noted that voltage provision circuit 700, at its output stage, includes one pull-up transistor 730 and one pull-down transistor 732 connected to each other with their drain terminals to provide the operation voltage VDDQ.

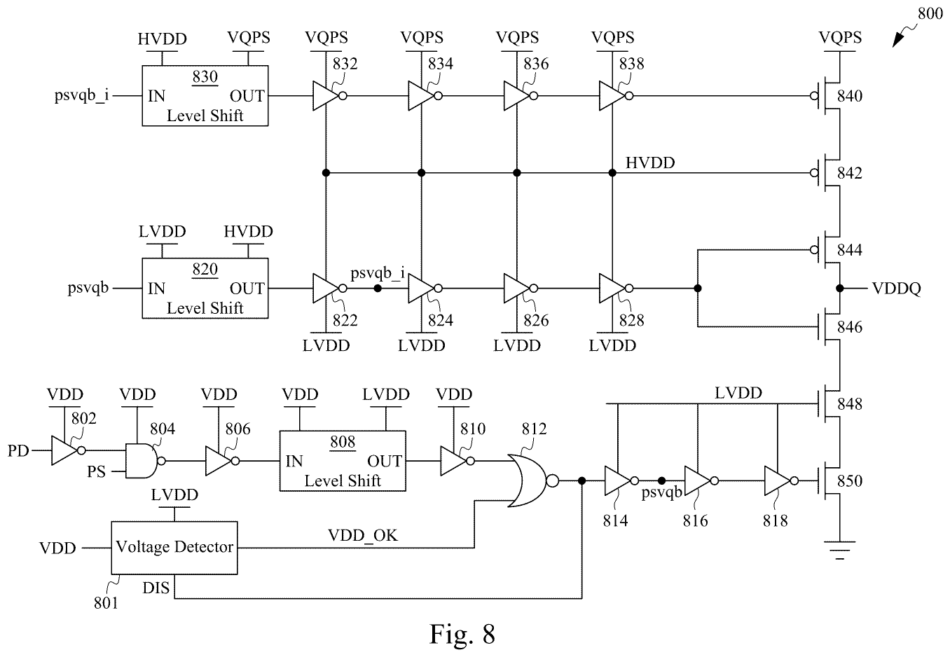

FIG. 8 illustrates an example circuit diagram of a voltage provision circuit 800 of the I/O circuit 108, in accordance with some embodiments. The voltage provision circuit 800 can provide an operation voltage (VDDQ) configured for programming the efuse cell 103. The voltage provision circuit 800 is substantially similar to the voltage provision circuit 500 (FIG. 5), both of which can provide the operation voltage VDDQ shifted from a first voltage domain (e.g., from 0V to about 0.75V) to a second voltage domain (e.g., from 0V to about 1.8V) with a stacked structures, except that the voltage provision circuit 800 may have its components powered by respective different mid-range supply voltages, LVDD and HVDD. In general, the second supply voltage VQPS is higher than the mid-range supply voltage HVDD, which is higher than the mid-range supply voltage LVDD, which is higher than the ground voltage. For example, the mid-range voltage LVDD may be configured as ⅓×VQPS, and the mid-range supply voltage HVDD may be configured as ⅔×VQPS. For brevity, the following discussion on the voltage provision circuit 800 will be focused on the difference.

In comparison with the voltage provision circuit 500 (FIG. 5), the voltage provision circuit 800 also includes components 801, 802, 804, 806, 808, 810, 812, 814, 816, 818, 820, 822, 824, 826, and 828, which are similar to the components 501, 502, 504, 506, 508, 510, 512, 514, 516, 518, 520, 522, 524, 526, and 528, respectively, except the following difference. For example, the voltage detector 801, which can include the components shown in FIG. 4, can have its inverter coupled between a first mid-range supply voltage LVDD (e.g., about 0.6V) and the ground voltage. As a result, the voltage detector 801 can receive the first supply voltage VDD in the first voltage domain (from 0V to about 0.75V) and output the control signal VDD_OK in another (third) voltage domain (from 0V to about 0.6V). The voltage detector 801 can output the control signal VDD_OK at the logic high state (e.g., about 0.6V) upon detecting that the first supply voltage VDD is at the logic low state and the first mid-range supply voltage LVDD is at the logic high state. In another example, the level shifter 820 is configured to shift the control signal psvqb from the third voltage domain (e.g., from 0V to about 0.6V) to yet another (fourth) voltage domain. In some embodiments, the fourth voltage domain can range from the first mid-range supply voltage LVDD (e.g., about 0.6V) to a second mid-range supply voltage, HVDD, which is about 1.2V. Accordingly, the inverters 822 to 822, coupled to the output of the level shifter 820, can operate in the fourth voltage domain.

Further, the voltage provision circuit 800 includes level shifter 830, inverters 832, 834, 836, and 838, pull-up transistors 840, 842, and 844, and pull-down transistors 846, 848, and 850. The level shifter 830 can receive control signal psvqb_i from the inverter 822, which is in the fourth voltage domain (about 0.6˜1.2V), and shift it to yet another (fifth) voltage domain. In some embodiments, the fifth voltage domain can range from the second mid-range supply voltage HVDD (e.g., about 1.2V) to the second supply voltage VQPS (e.g., about 1.8V). Accordingly, the inverters 832 to 838, coupled to the output of the level shifter 830, can operate in the fifth voltage domain.

The pull-up transistors 840 to 844 and the pull-down transistors 846 to 850 can still be coupled between the second supply voltage VQPS and the ground voltage, with the transistors 844 and 846 having their drain terminals connected to each other to provide the operation voltage VDDQ. Specifically, the pull-up transistor 840 can have its gate terminal configured to receive a signal output from the inverter 838 (in the fifth voltage domain, from about 1.2V to about 1.8V); the pull-up transistor 842 can have its gate terminal configured to receive the second mid-range supply voltage HVDD (in the fourth voltage domain, from about 0.6V to about 1.2V); the pull-up transistor 844 and pull-down transistor 846 can have their gate terminals configured to receive a signal output from the inverter 828 (in the fourth voltage domain, from about 0.6V to about 1.2V); the pull-down transistor 848 can have its gate terminal configured to receive the first mid-range supply voltage LVDD (in the third voltage domain, from 0V to about 0.6V); and the pull-down transistor 850 can have its gate terminal configured to receive a signal output from the inverter 818 (in the third voltage domain, from 0V to about 0.6V).

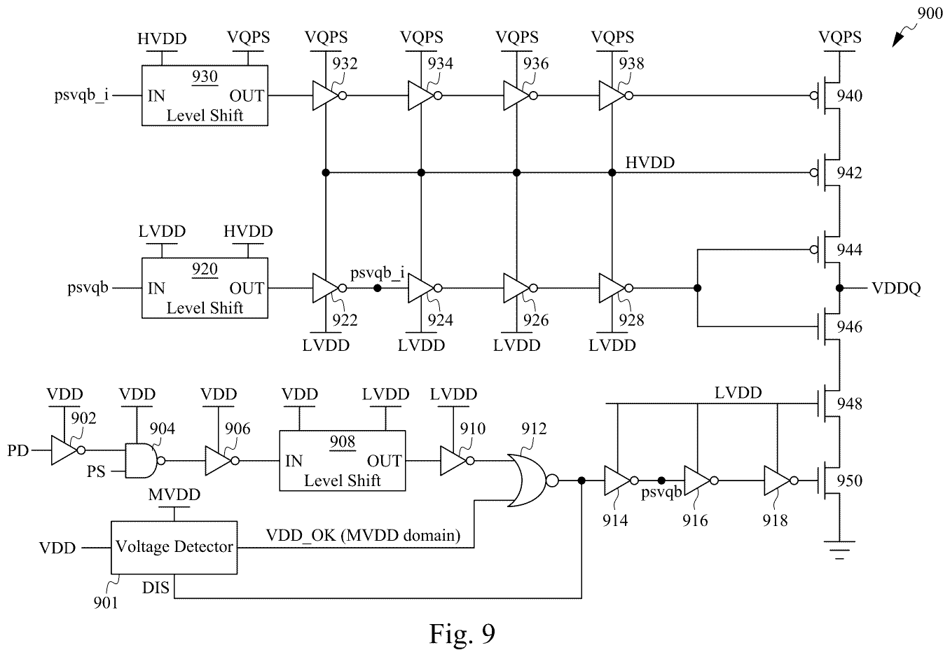

FIG. 9 illustrates an example circuit diagram of a voltage provision circuit 900 of the I/O circuit 108, in accordance with some embodiments. The voltage provision circuit 900 can provide an operation voltage (VDDQ) configured for programming the efuse cell 103. The voltage provision circuit 900 is substantially similar to the voltage provision circuit 800 (FIG. 8), both of which can provide the operation voltage VDDQ shifted from a first voltage domain (e.g., from 0V to about 0.75V) to a second voltage domain (e.g., from 0V to about 1.8V) with a stacked structures, except that the voltage provision circuit 900 may have its voltage detector (e.g., 901) powered by a third mid-range supply voltage, MVDD. In general, the second supply voltage VQPS is higher than the mid-range supply voltage HVDD, which is higher than the mid-range supply voltage MVDD, which is higher than the mid-range supply voltage LVDD, which is higher than the ground voltage. For example, the mid-range voltage LVDD may be configured as ⅓×VQPS, the mid-range supply voltage MVDD may be configured as ½×VQPS, and the mid-range supply voltage HVDD may be configured as ⅔×VQPS. For brevity, the following discussion on the voltage provision circuit 900 will be focused on the difference.

In comparison with the voltage provision circuit 800 (FIG. 8), the voltage provision circuit 900 also includes components 901, 902, 904, 906, 908, 910, 912, 914, 916, 918, 920, 922, 924, 926, 928, 930, 932, 934, 936, 938, 940, 942, 944, 946, 948, and 950, which are similar to the components 801, 802, 804, 806, 808, 810, 812, 814, 816, 818, 820, 822, 824, 826, 828, 830, 832, 834, 836, 838, 840, 842, 844, 846, 848, and 850, respectively, except that the voltage detector 901, which can include the components shown in FIG. 4, can have its inverter coupled between the mid-range supply voltage MVDD (e.g., about 0.9V) and the ground voltage. As a result, the voltage detector 901 can receive the first supply voltage VDD in the first voltage domain (from 0V to about 0.75V) and output the control signal VDD_OK in yet another voltage domain (from 0V to about 0.9V). For example, the voltage detector 901 can output the control signal VDD_OK at the logic high state (e.g., about 0.9V) upon detecting that the first supply voltage VDD is at the logic low state and the mid-range supply voltage MVDD is at the logic high state.

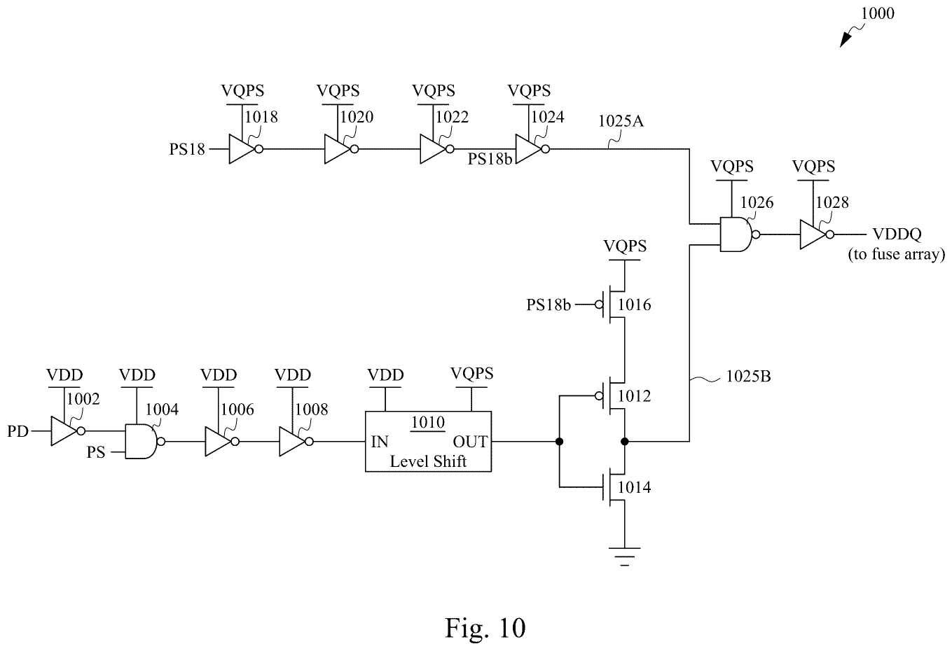

FIG. 10 illustrates an example circuit diagram of a voltage provision circuit 1000 of the I/O circuit 108, in accordance with some embodiments. The voltage provision circuit 1000 can provide an operation voltage (VDDQ) configured for programming the efuse cell 103. Similar to the voltage provision circuit 300 (FIG. 3), the voltage provision circuit 1100 can provide the operation voltage VDDQ shifted from a first voltage domain (e.g., from 0V to about 0.75V) to a second voltage domain (e.g., from 0V to about 1.8V), except that the voltage provision circuit 1100 may receive another control signal PS18 through another pin. Accordingly, the following discussion on the voltage provision circuit 1100 will be focused on the difference.

As shown, the voltage provision circuit 1000 includes inverter 1002, NAND gate 1004, inverter 1006, inverter 1008, level shifter 1010, p-type transistor 1016, p-type transistor 1018, n-type transistor 1014, inverter 1018, inverter 1020, inverter 1022, inverter 1024, NAND gate 1026, and inverter 1028. In some embodiments, the inverters 1002 to 1008 may operate in the first voltage domain and the transistors 1012 to 1016, the inverters 1018 to 1024, the NAND gate 1026, and the inverter 1028 may operate in the second voltage domain, with the level shifter 1010 shifting the first voltage domain to the second voltage domain.

In operation (when the coupled memory cell 103 is configured in the program mode), control signals PD, PS, and PS18 are provided at a logic low state, a logic high state, and the logic high state, respectively (i.e., PD=0, PS=1, PS18=1). As a result, input signals 1025A and 1025B, received by the NAND gate 1026, are both provided at the logic high state, which causes the inverter 1028 to output the operation voltage VDDQ equal to the second supply voltage VQPS at the logic high state (e.g., at about 1.8V). For example, when PD=0 and PS=1, the NAND gate 1004 outputs a signal with the logic high state, causing the level shifter 1010 to receive its input signal at the logic low state (e.g., 0V in the first voltage domain) and provide an output signal also at the logic low state (e.g., 0V in the second voltage domain). An inverter, formed by the transistors 1012 and 1014, can output the signal 1025B at the logic high state. On the other hand, when PS18=1, the inverter chain 1018 to 1014 can output the signal 1025A at the logic high state. Upon receiving both of its input signals at the logic high state, the NAND gate 1026 can output a signal at the logic low state, which is then inverted to the logic high state through the inverter 1028.

In certain scenarios, when the coupled memory cell 103 is configured in the program mode but PS18=1 but PS=0, the voltage provision circuit 1000 can output the operation voltage VDDQ equal to the second supply voltage VQPS at the logic low state (e.g., at 0V). Such scenarios can happen when the first supply voltage VDD is not properly provided. For example, when PS=0, the signal 1025B, received by the NAND gate 1026, becomes the logic low state, which causes the NAND gate 1026 to output the signal with the logic high state. Consequently, the operation voltage VDDQ is then provided with the logic low state (e.g., at 0V) through the inverter 1028.

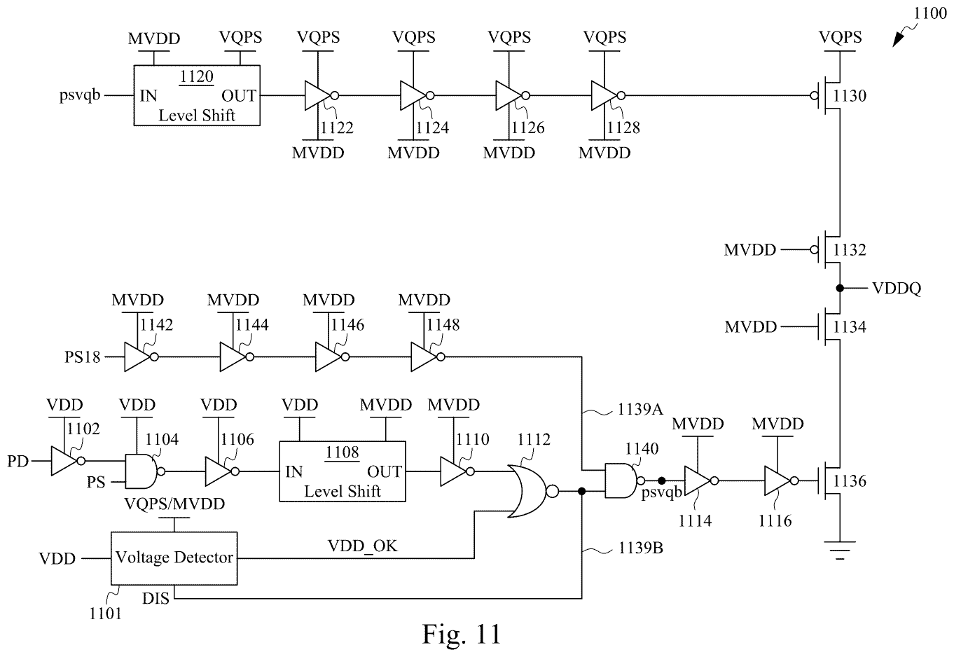

FIG. 11 illustrates an example circuit diagram of a voltage provision circuit 1100 of the I/O circuit 108, in accordance with some embodiments. The voltage provision circuit 1100 can provide an operation voltage (VDDQ) configured for programming the efuse cell 103. Similar to the voltage provision circuit 500 (FIG. 5), the voltage provision circuit 1100 can provide the operation voltage VDDQ shifted from a first voltage domain (e.g., from 0V to about 0.75V) to a second voltage domain (e.g., from 0V to about 1.8V), except that the voltage provision circuit 1100 may receive another control signal PS18 through another pin. Accordingly, the following discussion on the voltage provision circuit 1100 will be focused on the difference.

Similar to the voltage provision circuit 500, the voltage provision circuit 1100 also includes components 1102, 1104, 1106, 1108, 1110, 1112, 1114, 1116, 1118, 1120, 1122, 1124, 1126, 1128, 1130, 1132, 1134, and 1136, which are similar to the components 502, 504, 506, 508, 510, 512, 514, 516, 518, 520, 522, 524, 526, 528, 530, 532, 534, and 536, respectively. Further, the voltage provision circuit 1100 includes NAND gate 1140, and inverters 1140, 1142, 1146, and 1148. The NAND gate 1140 is configured to receive its input signals 1139A and 1139B through the inverter chain 1042 to 1048 and through the voltage detector 1101, respectively, and provide control signal psvqb by performing a NAND operation on the signals 1139A and 1139B. For example, the signal 1139B may be the same as the control signal DIS, which may only be at the logic high state when the first supply voltage VDD and the second supply voltage VQPS (or the powering mid-range supply voltage MVDD) are both provided at the high logic state; and the signal 1139A may have the same logic state as the received control signal PS18.

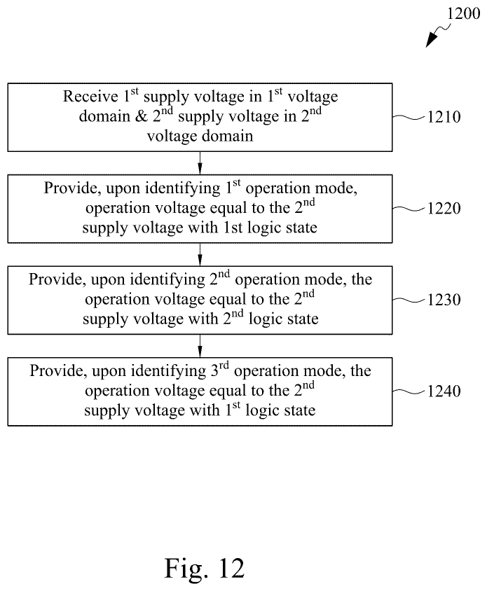

FIG. 12 illustrates a flow chart of an example method 1200 for providing an operation voltage to a memory circuit, in accordance with some embodiments. The operations of the method 1200 may be performed by the components described above (e.g., FIGS. 3-11), and thus, some of the reference numerals used above may be re-used the following discussion of the method 1200. Further, it is understood that the method 1200 has been simplified, and thus, additional operations may be provided before, during, and after the method 1200 of FIG. 12, and that some other operations may only be briefly described herein.

The method 1200 starts with operation 1210 of receiving a first supply voltage transitioning in a first voltage domain and a second supply voltage transitioning in a second voltage domain, in which the first voltage domain is different from the second voltage domain. Using the voltage provision circuit 300 as a non-limiting example, the voltage provision circuit 300 can receive the first supply voltage (e.g., VDD) and the second supply voltage (e.g., VQPS) with their respective logic states. The first supply voltage can transition in a first voltage domain (e.g., from 0V to VDD which can be set at about 0.75V), and the second supply voltage can transition in a second voltage domain (e.g., from 0V to VQPS which can be set at about 1.8V) different from the first voltage domain. For instance, when provided at a logic high state, the voltage provision circuit 300 can receive the first supply voltage equal to 0.75V; and when provide at a logic low sate, the voltage provision circuit 300 can receive the first supply voltage equal to 0V. Similarly, when provided at a logic high state, the voltage provision circuit 300 can receive the second supply voltage equal to 1.8V; and when provide at a logic low sate, the voltage provision circuit 300 can receive the second supply voltage equal to 0V.

The method 1200 continues to operation 1220 of providing, upon identifying a memory circuit configured in a first operation mode, an operation voltage equal to the second supply voltage with a first logic state. Continuing with the above example, when the coupled memory circuit (e.g., memory cell 103) is configured in a read mode, the voltage provision circuit 300 may provide the operation voltage (VDDQ) equal to the second supply voltage at the logic low state, e.g., 0V. In some embodiments, the voltage provision circuit 300 can determine that the memory circuit is in the read mode by identifying that the control signals PD and PS are both configured at the logic low state, and the first and second supply voltages VDD and VQPS are both provided at the logic high state.

The method 1200 continues to operation 1230 of providing, upon identifying the memory circuit configured in a second operation mode, the operation voltage equal to the second supply voltage with a second logic state. Continuing with the above example, when the coupled memory circuit (e.g., memory cell 103) is configured in a program mode, the voltage provision circuit 300 may provide the operation voltage (VDDQ) equal to the second supply voltage at the logic high state, e.g., 1.8V. In some embodiments, the voltage provision circuit 300 can determine that the memory circuit is in the program mode by identifying that the control signal PD is configured at the logic low state, the control signal PS is configured at the logic high state, and the first and second supply voltages VDD and VQPS are both provided at the logic high state.

The method 1200 continues to operation 1240 of providing, upon identifying the memory circuit configured in a third operation mode, the operation voltage equal to the second supply voltage with the first logic state. Continuing with the above example, when the coupled memory circuit (e.g., memory cell 103) is configured in a non-program or non-read mode (sometimes referred to as a legal or transition mode), the voltage provision circuit 300 may provide the operation voltage (VDDQ) equal to the second supply voltage at the logic low state, e.g., 0V. For example, such a transition mode can occur during switching between the read mode and program mode, where the second supply voltage VQPS has reached the logic high state but the first supply VDD remains at the logic low state. In some embodiments, the voltage provision circuit 300 can determine that the memory circuit is in the legal mode by identifying that the control signals PD and PS are not configured, the first supply voltage VDD is provided at the logic low state, and second supply voltage VQPS is provided at the logic high state.

In one aspect of the present disclosure, a circuit is disclosed. The circuit includes a memory array comprising a plurality of memory cells; and a voltage provision circuit configured to provide an operation voltage for one or more of the plurality of memory cells, the operation voltage being shifted from a first voltage domain to a second voltage domain. The voltage provision circuit comprises a voltage detector, and wherein the voltage detector, powered by a second supply voltage in the second voltage domain, is configured to receive a first supply voltage in the first voltage domain and provide a first control signal, the first control signal being configured to determine whether the operation voltage is equal to the second supply voltage at a first logic state or the second supply voltage at a second logic state.

In another aspect of the present disclosure, a circuit is disclosed. The circuit includes a voltage detector, powered by a first supply voltage in a first voltage domain, that is configured to receive a second supply voltage in a second voltage domain and provide a first control signal, wherein the first supply voltage at a logic high state is higher than the second supply voltage at the logic high state; a logic gate configured to provide a second control signal based on the first control signal, the first and second control signals being in the first voltage domain; and a first n-type transistor having a gate terminal configured to receive the second control signal through a first inverter, a drain terminal coupled to an output node for providing a memory circuit with an operation voltage, and a source terminal coupled to a ground voltage. The second control signal is outputted by the logic gate at the logic high state even if the first supply voltage is provided with the logic high state and the second supply voltage is provided with a logic low state.

In yet another aspect of the present disclosure, a method for providing an operation voltage to a memory circuit is disclosed. The method includes receiving a first supply voltage transitioning in a first voltage domain and a second supply voltage transitioning in a second voltage domain, the first voltage domain being different from the second voltage domain. The method includes providing, upon identifying a memory circuit configured in a first operation mode, an operation voltage equal to the second supply voltage with a first logic state. The method includes providing, upon identifying the memory circuit configured in a second operation mode, the operation voltage equal to the second supply voltage with a second logic state. The method includes providing, upon identifying the memory circuit configured in a third operation mode, the operation voltage equal to the second supply voltage with the first logic state. In the first operation mode, the first supply voltage and the second supply voltage are each provided with the second logic state. In the second operation mode, the first supply voltage and the second supply voltage are each provided with the second logic state. In the third operation mode, the first supply voltage and the second supply voltage are provided with the first logic state and the second logic state, respectively.

As used herein, the terms “about” and “approximately” generally indicates the value of a given quantity that can vary based on a particular technology node associated with the subject semiconductor device. Based on the particular technology node, the term “about” can indicate a value of a given quantity that varies within, for example, 10-30% of the value (e.g., ±10%, ±20%, or ±30% of the value).

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A circuit, comprising:
a memory array comprising a plurality of memory cells; and
a voltage provision circuit configured to provide an operation voltage for one or more of the plurality of memory cells, the operation voltage being shifted from a first voltage domain to a second voltage domain;
wherein the voltage provision circuit comprises a voltage detector, and wherein the voltage detector is configured to receive a first supply voltage in the first voltage domain, powered by a second supply voltage in the second voltage domain, and provide a first control signal, the first control signal being configured to determine whether the operation voltage is equal to the second supply voltage at a first logic state or the second supply voltage at a second logic state.

2. The circuit of claim 1, wherein the voltage provision circuit further comprises:
a NOR gate configured to receive the first control signal and provide a second control signal;
a first inverter configured to receive the second control signal and provide a third control signal; and
a second inverter configured to receive the third control signal and provide the operation voltage;
wherein each of the NOR gate, the first inverter, and the second inverter is powered by the second supply voltage.

3. The circuit of claim 1, wherein the voltage detector comprises a third inverter, powered by the second supply voltage, that is configured to receive the first supply voltage and provide the first control signal.

4. The circuit of claim 3, wherein, when the first supply voltage and the second supply voltage are provided at the first logic state and the second logic state, respectively, the first control signal is provided at the second logic state, causing the voltage provision circuit to provide the operation voltage equal to the second supply voltage at the first logic state.

5. The circuit of claim 3, wherein the voltage detector further comprises an n-type transistor coupled between an input of the third inverter and a ground voltage, with its gate terminal connected to a second control signal determined based on NOR'ing the first control signal.

6. The circuit of claim 5, wherein, when the first supply voltage and the second supply voltage are both provided at the second logic state, the second control signal is kept at the second logic state.

7. The circuit of claim 5, wherein the voltage detector further comprises a Schmitt trigger coupled to an output of the third inverter.

8. The circuit of claim 1, wherein the plurality of memory cells each include a one-time-programmable (OTP) memory cell.

9. A circuit, comprising:
a voltage detector, powered by a first supply voltage in a first voltage domain, that is configured to receive a second supply voltage in a second voltage domain and provide a first control signal, wherein the first supply voltage at a logic high state is higher than the second supply voltage at the logic high state;
a logic gate configured to provide a second control signal based on the first control signal, the first and second control signals being in the first voltage domain; and
a first n-type transistor having a gate terminal configured to receive the second control signal through a first inverter, a drain terminal coupled to an output node for providing a memory circuit with an operation voltage, and a source terminal coupled to a ground voltage;
wherein the second control signal is outputted by the logic gate at the logic high state even if the first supply voltage is provided with the logic high state and the second supply voltage is provided with a logic low state.

10. The circuit of claim 9, wherein the logic gate includes a NOR logic gate.

11. The circuit of claim 9, further comprising a first p-type transistor having a gate terminal configured to receive the second control signal through the first inverter, a drain terminal connected to the output node, and a source terminal connected to the first supply voltage.

12. The circuit of claim 11, further comprising a level shifter configured to shift a signal from the second voltage domain to the first voltage domain.

13. The circuit of claim 11, wherein the operation voltage, provided at the output node, is equal to the first supply voltage at the logic high state or at the logic low state, depending on a logic state of the second control signal.

14. The circuit of claim 9, further comprising:
a second n-type transistor having a gate terminal configured to receive the first supply voltage, a drain terminal connected to the output node, and a source terminal connected to the drain terminal of the first n-type transistor;
a first p-type transistor having a gate terminal configured to receive the first supply voltage, a drain terminal connected to the output node, and a source terminal coupled to a third supply voltage in a third voltage domain, wherein the third supply voltage is higher than the first supply voltage; and
a second p-type transistor having a gate terminal configured to receive a third control signal, a drain terminal connected to the source terminal of the first p-type transistor, and a source terminal connected to the third supply voltage.

15. The circuit of claim 14, wherein the operation voltage, provided at the output node, is equal to the third supply voltage at the logic high state or at the logic low state, depending on a logic state of the second control signal and a logic state of the third control signal, and the third control signal being in the third voltage domain.

16. The circuit of claim 15, further comprising:
a first level shifter configured to shift a signal from the second voltage domain to the first voltage domain; and
a second level shifter configured to shift a signal from the first voltage domain to the third voltage domain.

17. The circuit of claim 9, wherein the voltage detector comprises an inverter, powered by the first supply voltage, that has an input configured to receive the second supply voltage and an output configured to provide the first control signal.

18. The circuit of claim 17, wherein the voltage detector further comprises a second n-type transistor coupled between the input of the inverter and a ground voltage, with its gate terminal configured to receive the second control signal.

19. A method for providing an operation voltage to a memory circuit, comprising:
receiving a first supply voltage transitioning in a first voltage domain and a second supply voltage transitioning in a second voltage domain, the first voltage domain being different from the second voltage domain;
providing, upon identifying a memory circuit configured in a first operation mode, an operation voltage equal to the second supply voltage with a first logic state;
providing, upon identifying the memory circuit configured in a second operation mode, the operation voltage equal to the second supply voltage with a second logic state; and
providing, upon identifying the memory circuit configured in a third operation mode, the operation voltage equal to the second supply voltage with the first logic state;
wherein, in the first operation mode, the first supply voltage and the second supply voltage are each provided with the second logic state, wherein, in the second operation mode, the first supply voltage and the second supply voltage are each provided with the second logic state, and wherein, in the third operation mode, the first supply voltage and the second supply voltage are provided with the first logic state and the second logic state, respectively.

20. The method of claim 19, wherein the second supply voltage in the second logic state is higher than the first supply voltage in the second logic state.
